(19) United States
(12) Patent Application Publication
(10) Pub. No.: US 2017/0171593 A1
(43) Pub. Date: Jun. 15, 2017

(54) TUNER UNIT MODULE, TUNER AND ELECTRONIC DEVICE

(71) Applicants: Le Holdings (Beijing) Co., Ltd., Beijing (CN); LE SHI ZHI XIN ELECTRONIC TECHNOLOGY (TIANJIN) LIMITED, Beijing (CN)

(72) Inventors: Xue Jinsheng, Beijing (CN); Zhang Wen, Beijing (CN); Liu Song, Beijing (CN)

(21) Appl. No.: 15/246,855

(22) Filed: Aug. 25, 2016

Related U.S. Application Data
(63) Continuation of application No. PCT/CN2016/088657, filed on Jul. 5, 2016.

(30) Foreign Application Priority Data
Dec. 14, 2015 (CN) 201521041714.3

(51) Int. Cl. H04N 21/426; H04N 5/50; H04N 5/46; H05K 5/04

(52) U.S. Cl. CPC H04N 21/4263; H05K 5/04; H04N 5/50; H04N 5/46

(57) ABSTRACT

Embodiments of the present disclosure provide a tuner unit module, which includes at least one tuner chip, and the tuner unit module is provided with a first preset number of input pins and a second preset number of output pins; and the input pins are used to connect the output interfaces of a preset radio frequency receiving unit in a one-to-one correspondence manner, and the output pins are used to connect the input interfaces of a preset TV motherboard in the one-to-one correspondence manner. The tuner unit module provided by the present disclosure is provided with unified input pins and unified output pins, when the tuner unit module needs improvement, only the tuner chip therein needs to be changed without changing the entire tuner unit module, therefore, there is no need to manufacture the TV motherboard that adapts to the new tuner unit module, and thus the cost is saved.

### CROSS-REFERENCE TO RELATED APPLICATIONS

The present disclosure cites Chinese Application No. 201521041714.3, filed on Dec. 14, 2015, and entitled “Tuner Unit Module, Tuner and Electronic Device”.

### TECHNICAL HELD

Embodiments of the present disclosure relates to the technical field of electronic devices, and in particular, to a tuner unit module, a tuner and an electronic device.

### BACKGROUND

At present, radio frequency standards vary between countries, resulting in that different versions of TV motherboards need to be manufactured due to different tuners on the export market, and due to the technical and technological innovation, the update and replacement of electronic tuners are faster and faster. During implementation of the present disclosure, the inventors have found that the prior art at least has the following problems: in order to adapt to a new tuner and be compatible with the original performance at the same time, the difficulty of PCB wiring of the TV motherboards is increased, and great waste is caused in product design and cost.

### SUMMARY

The object of the present disclosure is to provide a tuner unit module, a tuner and an electronic device. The tuner unit module provided by the present disclosure is provided with unified input pins and unified output pins, when the tuner unit module needs to be improved, only a tuner chip therein needs to be changed without changing the entire tuner unit module, therefore, there is no need to manufacture a TV motherboard that adapts to the new tuner unit module, and thus the cost is saved.

To achieve the above object, embodiments of the present disclosure provides a tuner unit module. The tuner unit module includes at least one tuner chip, and the tuner unit module is provided with a first preset number of input pins and a second preset number of output pins; and

The input pins are used e output interfaces of a preset radio frequency receiving unit in a one-to-one correspondence manner, and the output pins are used to connect the input interfaces of a preset TV motherboard in the one-to-one correspondence manner.

Optionally, the first preset number is 5, and the second preset number is 8.

Optionally, the first preset number is 9, and the second preset number is 20.

Optionally, the first preset number is 12, and the second preset number is 22.

Optionally, the first preset number is 20, and the second preset number is 30.

Optionally, the tuner chip is a full-standard tuner chip or a semi-standard tuner chip.

Optionally, the tuner unit module is packaged by a metal shielding case, and the input pins and the output pins are placed on the outer side of the metal shielding case.

The embodiments of the present disclosure further provide a tuner, including a radio frequency receiving unit and the above tuner unit module.

The embodiments of the present disclosure further provide an electronic device, including the above tuner.

According to the timer unit module provided by the embodiments of the present disclosure, since the tuner unit module has the unified input pins and the unified output pins, when the tuner unit module needs to be updated or improved, only the tuner chip therein needs to be changed without changing the entire tuner unit module, therefore, there is no need to manufacture the TV motherboard that adapts to the new tuner unit module, and thus the design cost and the manufacturing cost of the TV motherboard are saved.

### BRIEF DESCRIPTION OF THE DRAWINGS

To illustrate technical solutions in the embodiments of the present disclosure or in the prior art more clearly, a brief introduction on the accompanying drawings to be used in the description of the embodiments or the prior art will be given below. Apparently, the accompanying drawings in the description below are merely some of the embodiments of the present disclosure, based on which other drawings can be obtained by those of ordinary skill in the art without any creative effort.

FIG. 1 shows a schematic diagram of a structure of a tuner unit module provided by a first embodiment of the present disclosure;

FIG. 2 shows a schematic diagram of a structure of a tuner provided by a second embodiment of the present disclosure.

### DETAILED DESCRIPTION

In order to make the object, technical solutions and advantages of the present disclosure clearer, a clear and complete description of technical solutions in the embodiments of the present disclosure will be given below, in combination with the accompanying drawings in the embodiments of the present disclosure. Apparently, the embodiments described are merely a part, but not all, of the embodiments of the present disclosure. All of other embodiments, obtained by those of ordinary skill in the art based on the embodiments of the present disclosure without any creative effort, fall into the protection scope of the present disclosure.

Since an electronic tuner is updated too fast, if it is replaced with a new timer, the PCB wiring of a TV motherboard needs to be replanned, resulting in a very large workload and a relatively long research and development cycle. In addition, the radio frequency formats of different countries are different, and different demands result in a wide variety of motherboards, such that unification cannot be realized, and management and cost are very difficult to manage and control. In view of the above problems, a first embodiment of the present disclosure provides a tuner unit module.

### First Embodiment

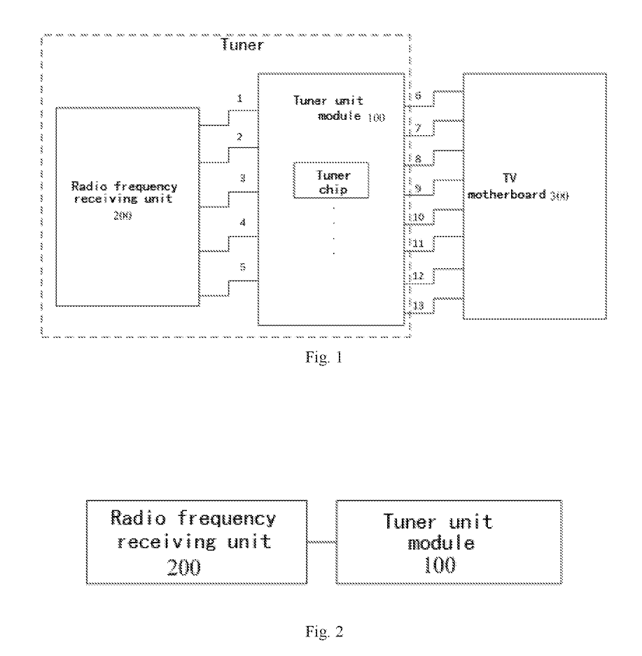

Referring to FIG. 1, the tuner unit module 100 provided by the embodiment includes at least one tuner chip, and the tuner unit module is provided with a first preset number of input pins and a second preset number of output pins; and

the input pins are used for connection with output interfaces of a preset radio frequency receiving unit in a one-to-one correspondence manner, and the output pins are used for connection with input interfaces of a preset TV motherboard in the one-to-one correspondence manner.

In FIG. 1, the pins 1-5 are input pins and are used for connection with the radio frequency receiving unit 200; and the pins 6-13 are output pins and are used for connection with the TV motherboard 300.

When the tuner chip in the tuner unit module in FIG. 1 is changed into another tuner chip, the connection relation between the input pins used for connection with the radio frequency receiving unit 200 in the tuner unit module 100 and the output interfaces of the radio frequency receiving unit 200 is invariable, and the connection relation between the output pins used for connection with the TV motherboard 300 in the tuner unit module 100 and the input interfaces of the TV motherboard 300 is invariable.

According to the tuner unit module provided by the embodiment, since the tuner unit module has the unified input pins and the unified output pins, when the tuner unit module needs to be updated or improved, only the tuner chip therein needs to be changed without changing the entire tuner unit module, therefore, there is no need to manufacture the TV motherboard that adapts to the new tuner unit module, and thus the design cost and the manufacturing cost of the TV motherboard are saved.

Optionally, the first preset number can also be 9, and the second preset number can also be 20. Or, optionally, the first preset number can also be 12, and the second preset number can also be 22. Or, optionally, the first preset number can also be 20, and the second preset number can also be 30.

Optionally, the tuner chip is a full-standard tuner chip or a semi-standard tuner chip. When the tuner chip is the full-standard tuner chip, a tuner composed of the tuner unit module can adapt to different tuning standards in the world.

Meanwhile, no matter the tuner unit module supports full-standard tuning or semi-standard tuning, the TV motherboard adapting to the tuner unit module is consistent. Therefore, the TV motherboard does not need to be redesigned or changed due to the changes of the radio frequency demand on the export market, in this way, the design and manufacturing costs of the TV motherboard are saved, and meanwhile, the efficiency is improved as well.

In addition, for different radio frequency standard demands, since the structure or wiring of the TV motherboard is consistent, the design and the manufacture of the TV motherboard can be uniformly managed, and thus the cost is further reduced.

In order to improve the ability of the tuner unit module to tune radio frequency signals and facilitate installation and storage, the tuner unit module is packaged by a metal shielding case, and the input pins and the output pins are placed on the outer side of the metal shielding case.

In summary, in the present disclosure, the tuner unit module is invariable, so when the tuner unit module needs improvement, only the tuner chip therein needs to be changed, without changing the input and output of the tuner unit module, and therefore the TV motherboard adapting to the tuner unit module requires no rewiring.

### Second Embodiment

The second embodiment of the present disclosure provides a tuner. Referring to FIG. 2, the tuner includes a radio frequency receiving unit 200 and the timer unit module 100 in the above embodiment.

In the embodiment, the radio frequency receiving unit 200 of the tuner sends a received radio frequency signal to the tuner unit module 100, the tuner chip in the tuner unit module 100 tunes the radio frequency signal into a medium frequency signal and sends the same to the TV motherboard, and the TV motherboard processes the medium frequency signal.

Since the tuner in the embodiment includes the tuner unit module in the above embodiment, when the tuner needs to be changed, only the tuner chip in the tuner unit module needs to be changed, without changing the TV motherboard adapting to the tuner, namely, when the tuner is updated, the TV motherboard requires no redesign, rewiring or remanufacture, so that the efficiency is improved, and the cost is reduced.

### Third Embodiment

The embodiment of the present disclosure provides an electronic device, including the tuner in the above embodiment. The electronic device can be a smart TV, a display or the like.

The apparatus embodiments described above are merely schematic, wherein units described as separate components can be separated physically or not, components displayed as units can be physical units or not, namely, can be located in one place, or can also be distributed on a plurality of network units. A part of or all modules therein can be selected to achieve the objects of the solutions in the embodiments according to actual demand. Those of ordinary skill in the art can understand and implement the objects without any creative effort.

Finally, it should be noted that the above-mentioned embodiments are merely used for illustrating rather than limiting the technical solutions of the embodiments of the present disclosure; although the embodiments of the present disclosure have been described in detail with reference to the foregoing embodiments, those of ordinary skill in the art should understand that they could still make modifications to the technical solutions recorded in the foregoing embodiments or make equivalent substitutions to a part of or all technical features therein; and these modifications or substitutions do not make the essence of the corresponding technical solutions depart from the scope of the technical solutions of the embodiments of the present disclosure.

1. A tuner unit module, wherein the tuner unit module comprises at least one tuner chip, and the tuner unit module is provided with a first preset number of input pins and a second preset number of output pins; and
the input pins are used to connect the output interfaces of a preset radio frequency receiving unit in a one-to-one correspondence manner, and the output pins are used to connect the input interfaces of a preset TV motherboard in the one-to-one correspondence manner.

2. The tuner unit module of claim 1, wherein the first preset number is 5, and the second preset number is 8.

3. The tuner unit module of claim 1, wherein the first preset number is 9, and the second preset number is 20.

4. The tuner unit module of claim 1, wherein the first preset number is 12, and the second preset number is 22.

5. The tuner unit module of claim 1, wherein the first preset number is 20, and the second preset number is 30.

6. The tuner unit module of claim 1, wherein the tuner chip is a multi-standard tuner chip.

7. The tuner unit module of claim 1, wherein the tuner unit module is packaged by a metal shielding case, and the input pins and the output pins are placed on the outer side of the metal shielding case.

8. A tuner, comprising a radio frequency receiving unit and the tuner unit module of any one of claim 1.

9. An electronic device, comprising the tuner of claim 8.
